(19) United States
(12) Patent Application Publication
(10) Pub. No.: US 2011/0194253 A1
(43) Pub. Date: Aug. 11, 2011

(54) SEMICONDUCTOR APPARATUS HAVING SEMICONDUCTOR MODULE COOLED BY HEAT SINKS WHICH HAVE INCREASED STRENGTH TOGETHER WITH INCREASED THERMAL MASS

(75) Inventor: Taijirou MOMOSE, Kariya-shi (JP)

(73) Assignee: DENSO CORPORATION, Kariya-city (JP)

(21) Appl. No.: 13/025,518

(22) Filed: Feb. 11, 2011

(30) Foreign Application Priority Data
Feb. 11, 2010 (JP) 2010-028326

(51) Int. Cl. H05K 7/20

(52) U.S. Cl. 361/697

(57) ABSTRACT

In a semiconductor apparatus, a semiconductor module containing semiconductor elements is enclosed between a pair of heat sinks which are held attached together by spring clips. Each heat sink has one side thermally coupled to a corresponding main face of the semiconductor module and has an array of primary fins and a pair of secondary fin protruding from the other side, with the secondary fins being located at opposing ends of the array of primary fins, beyond the outermost primary fins. At least part of each secondary fin is made thicker than each primary fin, to provide greater strength and greater thermal mass for each secondary fin than each primary fin.

### CROSS-REFERENCE TO RELATED APPLICATIONS

This application is based on and incorporates herein by reference Japanese Patent Application No. 2010-28326 filed on Feb. 11, 2010.

### BACKGROUND OF THE INVENTION

1. Field of Application

The present invention relates to a semiconductor apparatus consisting of a semiconductor module combined with heat sinks which dissipate heat that is generated by the semiconductor module.

2. Description of Related Art

Types of semiconductor apparatus are known which incorporate a semiconductor module and a heat sink which is thermally coupled to the semiconductor module, for cooling the module. The heat sink may contact the semiconductor module through the intermediary of a sheet of thermally conductive material, and/or a layer of thermally conductive grease, etc. Such a type of semiconductor apparatus is described for example in Japanese patent publication No. 2003-347783. With the semiconductor apparatus described in that patent disclosure, a noise blocking plate formed of an elastic material is located between a semiconductor module and a control circuit board which controls the operation of semiconductor elements in the semiconductor module, and an attachment portion of the noise blocking plate is fixed to a heat sink. A bent portion of the noise blocking plate is joined to the semiconductor module, and the heat sink is thereby held pressed against the semiconductor module with a predetermined amount of force.

However although the noise blocking plate serves to efficiently transfer heat from the semiconductor module to the heat sink, while also serving as a contact pressure determining member, so that the overall size of the semiconductor apparatus can be made compact and the manufacturing cost can be low, such a configuration does not provide satisfactory performance with respect to efficient dissipation of heat from the semiconductor module. In particular, in the case of air cooling of the heat sink, since the thermal transfer coefficient of air is small, it is necessary to make the total area of the thermal radiation faces of the heat sink substantially large.

This can be achieved by providing a large number of thermal radiation fins (referred to in the following simply as fins) on the heat sink. The number of fins can be increased by making each fin more thin. However as the fins are made thinner, these will more readily become distorted due to forces applied during or after the process of manufacture, e.g., due to physical contact with other parts of an equipment unit in which the semiconductor apparatus is installed. Such distortion of the fins can reduce the spacings between adjacent fins, and so lower the cooling efficiency (thermal transfer efficiency) of the heat sink. Hence it is difficult to achieve a suitable balance between the respective requirement for strength of the fins and thermal transfer efficiency with such a type of semiconductor apparatus.

### SUMMARY OF THE INVENTION

It is an objective of the present invention to overcome the above problem, by providing a semiconductor apparatus which combines a semiconductor module with a heat sink for cooling the semiconductor module, whereby the heat sink is configured such that there is a substantially reduced danger of deformation of the fins of the heat sink due to applied forces, while providing a sufficiently high thermal transfer efficiency.

It is a further objective of the invention to provide such a semiconductor apparatus, whereby the effective thermal mass of the heat sink is enhanced, thereby reducing the extent of fluctuations in temperature of the semiconductor module that result from short-term variations in the amount of heat generated by the semiconductor module.

According to a first aspect, a semiconductor apparatus according to the present invention comprises a semiconductor module which contains semiconductor elements and is formed with opposing sides having respective external main faces, and a pair of heat sinks which enclose between them the opposing sides of the semiconductor module. Each of the heat sinks is formed with a base portion having a first side that is thermally coupled to a corresponding one of the main faces of the semiconductor module, and has a plurality of primary fins respectively protruding from a second side of the base portion, the primary fins being successively arrayed along a first direction (referred to herein as the thickness direction) at regular spacings. In addition, each of the heat sinks also comprises at least one pair of secondary fins, each of the secondary fins having at least a part thereof formed with a thickness, as measured along the thickness direction, which is greater than a thickness of each of the primary fins. The secondary fins of each pair of secondary fins are located respectively outward from an outermost pair of the primary fins, as measured along the thickness direction.

Since the secondary fins have greater thickness than the primary fins, the volume (and hence, total mass) of a secondary fin can be made substantially greater than that of each primary fin. Hence, the thermal mass of each heat sink can be increased by incorporating the secondary fins (i.e., by comparison with the case in which the space occupied by each secondary fin would be instead occupied by primary fins). Hence, the heat storage capacity of each heat sink is increased, and since heat generated by the semiconductor elements is efficiently transferred to the secondary fins and temporarily stored there before being dissipated to the exterior, abrupt increases in temperature of the semiconductor elements can be prevented. Enhanced cooling performance can thereby be achieved.

Furthermore due to the increased thickness of each of the secondary fins, these have substantially greater strength than each primary fin. Such a semiconductor apparatus may installed within a case, e.g., with a plurality of the semiconductor apparatuses being tightly packed together within the case to prevent relative motion, so that fins of the heat sinks are held in contact with internal faces of the case and with other heat sinks. If all of the fins were configured as thin plates (for maximum efficiency of heat dissipation), bending of the fins could occur in such a condition. This can result in lowering of the cooling performance, due to reduction of the spacings between deformed fins. However by incorporating secondary fins on each heat sink, having greater strength against bending distortion than the primary fins, this problem is prevented.

From another aspect, for each pair of secondary fins of a heat sink, at least one secondary fin of that pair is made shorter than each of the primary fins, as measured along a second direction (referred to herein as the lateral direction) which is perpendicular to the thickness direction and parallel to the main faces of the semiconductor module. At least one fin-free region is thereby provided on each heat sink, i.e., on the opposite side of the heat sink from the main faces of the semiconductor module. This enables the heat sinks of a semiconductor apparatus to be clamped together, with the semiconductor module retained between them, simply by utilizing spring clips. Specifically, each spring clip engages against respectively corresponding fin-free regions of the opposed pair of heat sinks, applying forces acting to clamp the heat sinks against respective opposing main faces of the semiconductor module, and thereby thermally coupling the heat sinks to the semiconductor module. Since no components other than spring clips are required for this purpose, manufacture of the semiconductor apparatus is simplified, and manufacturing costs are minimized.

From another aspect, when the semiconductor apparatus is to be utilized in a condition of being contained within a case, one of the secondary fins of at least one of the pair of heat sinks of the semiconductor apparatus may be formed with a through-hole or a recessed portion, with an interior face of the case being formed with a corresponding protrusion, i.e., a protrusion which is positioned such as to engage within the through-hole or recessed portion of the secondary fin when the semiconductor apparatus is installed within the case. This enables the semiconductor apparatus to be readily set in a predetermined position and orientation within the case. In this case, the increased thickness of a secondary fin can enable the through-hole or recessed portion to be mad eof sufficient length (depth) for enabling the position of the semiconductor apparatus within the case to be securely established.

From another aspect, when the semiconductor apparatus is to be utilized in a condition of being contained within a case, one of the secondary fins of at least one of the pair of heat sinks of the semiconductor apparatus may be formed with a threaded hole, with a corresponding through-hole being formed in the case, positioned such as to correspond with the threaded hole when the semiconductor apparatus is installed within the case. The semiconductor apparatus can thereby be fixedly attached within the case, by means of a screw or bolt which is passed through the through-hole, engaged in the threaded hole and tightened.

In this case, the increased thickness of a secondary fin can enable a sufficient number of screw threads to be formed in the threaded hole for securely tightening a screw or bolt. It thereby becomes possible to securely fix the semiconductor apparatus within a case at a predetermined position and orientation by utilizing only a screw or bolt, i.e., without requiring the use of other components such as nuts.

From another aspect, a plurality of semiconductor apparatuses in accordance with the present invention can be utilized to produce a three-phase rectifier apparatus, having three circuit sections corresponding to respective ones of three phases. Each of the circuit sections is formed of interconnected circuit elements constituting an upper arm and interconnected circuit elements constituting a lower arm. The upper arm and each lower arm may be implemented by respective semiconductor modules of a pair of semiconductor apparatuses according to the present invention, i.e. with the three-phase rectifier apparatus being implemented by a total of six semiconductor apparatuses. These can be respectively disposed for enabling heat generated by the semiconductor modules to be efficiently transferred to the primary fins and secondary fins, and hence dissipated to the atmosphere.

Due to the increased strength provided by the secondary fins, these semiconductor apparatuses can be packed tightly together within a case. Specifically, the secondary fins of each semiconductor apparatus may be in direct contact with internal surfaces of the case and with adjacent semiconductor apparatuses, without danger of distortion of the primary fins. This enables the three-phase rectifier apparatus to be made highly compact. In addition to simplifying manufacture of the three-phase rectifier apparatus, this also enables the necessary number of parts to be reduced, i.e., by eliminating components which would hitherto have been necessary for securely attaching the semiconductor apparatuses within the case, or greatly reducing the number of such required attachment components. Manufacturing costs can thereby be reduced.

### BRIEF DESCRIPTION OF THE DRAWINGS

FIG. 1 is a conceptual diagram illustrating a 3-phase inverter apparatus functioning as a motor drive apparatus, incorporating a first embodiment of a semiconductor apparatus, installed in a vehicle;

FIG. 2 is a circuit diagram of the 3-phase inverter apparatus of FIG. 1;

FIG. 3 is an oblique exploded view of the first embodiment;

FIG. 4 is an oblique external view of the first embodiment;

FIG. 5 is an oblique external view of a set of six semiconductor apparatuses in accordance with the first embodiment, constituting part of the 3-phase inverter apparatus of FIG. 1, installed within a case;

FIG. 6 is an oblique external view of the inverter drive apparatus of FIG. 1;

FIG. 7 is a cross-sectional view in elevation corresponding to FIG. 5, illustrating the disposition of the semiconductor apparatuses within the case;

FIG. 8 is a cross-sectional view in elevation, for describing a second embodiment of a semiconductor apparatus;

FIG. 9 is a cross-sectional view in elevation, for describing a third embodiment of a semiconductor apparatus; and,

FIG. 10 is an oblique external view of a fourth embodiment of a semiconductor apparatus.

### DESCRIPTION OF PREFERRED EMBODIMENTS

Embodiments of the invention are described in the following referring to the drawings. In the following description, corresponding components within each of the different embodiment are designated throughout by identical reference numerals. When describing embodiments other than the first embodiment, only features of difference from previous embodiments are described in detail.

### First Embodiment

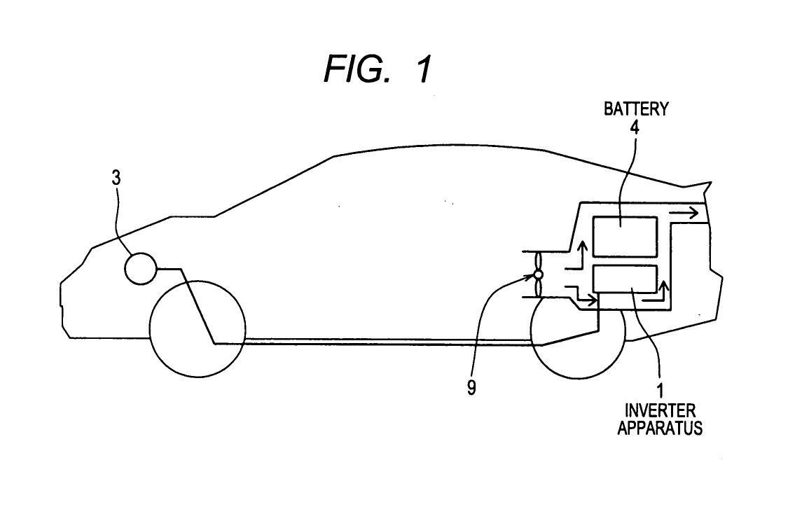

A first embodiment of a semiconductor apparatus will be described, which is suitable for use in an inverter apparatus for driving a high-power electric motor. The inverter apparatus serves to convert DC electrical power to AC power, and is typically a three-phase (U, V, W phases) inverter apparatus. The motor may be a drive motor of an electric vehicle that is powered by fuel cells such as is illustrated in the example of FIG. 1, or of a hybrid (gas/electric) vehicle.

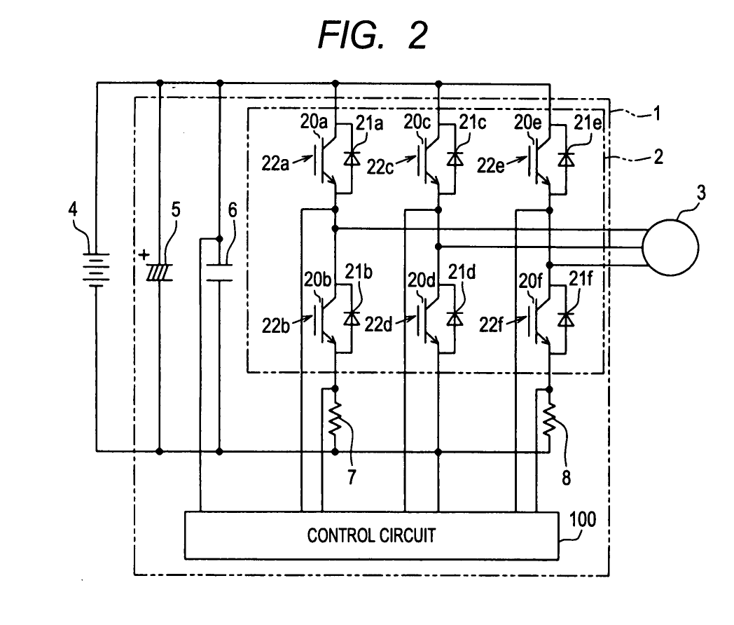

In the conceptual diagram of FIG. 1, an inverter apparatus 1 which is installed in a vehicle incorporates a three-phase inverter circuit, which drives a motor 3 to provide motive power for the vehicle. FIG. 2 is a circuit diagram of the three-phase inverter circuit, which incorporates six semiconductor apparatuses each in accordance with a first embodiment of the invention, as described hereinafter.

As shown in FIG. 1, the inverter apparatus 1 is installed at the rear end of the vehicle, adjacent to a battery 4, and is connected by wiring leads to the motor 3 which is installed at the front end of the vehicle. The inverter apparatus 1 is cooled by a flow of air (taken in from the exterior or the interior of the vehicle) which is impelled by a fan 9 through a duct, with the air passing through the inverter apparatus 1, then exhausted to the exterior of the vehicle. The manner in which the air flow passes through the inverter apparatus 1, to achieve effective cooling, is described in detail hereinafter.

In FIG. 2, within a power module 2, six semiconductor modules are respectively designated as 22a, 22b, 22c, 22d, 22e and 22f (collectively referred to by numeral 22 in the following). The circuit of the inverter apparatus 1 further includes resistors 7 and 8, a control circuit 100, and capacitors 4 and 5. As shown, the battery 4 is connected to the input side of the inverter apparatus 1, while the output side of the inverter apparatus 1 is connected to the electric motor 3.

The control circuit 100 controls the power module 2, for operating the power module 2 as a three-phase inverter circuit which converts the DC power of the battery 4 to AC power which is supplied to the electric motor 3. The semiconductor elements constituting the power module 2 are IGBTs (Insulated Gate Bipolar Transistors) 20a, 20b, 20c, 20d, 20e and 20f, and freewheeling diodes 21a, 21b, 21c, 21d, 21e and 21f. Each semiconductor module 22 contains one IGBT and one freewheeling diode.

The IGBTs 22a, 22b are connected in series, as are the IGBTs 22c, 22d and the IGBTs 22e, 22f. The collector electrodes of the IGBTs 20a, 20c and 20e (the IGBTs of the upper arms of the three-phase inverter circuit) are each connected to the positive terminal of the battery 4, while the emitter electrodes of the IGBTs 20b, 20d and 20f (the IGBTs of the lower arms of the three-phase inverter circuit) are each connected to the negative terminal of the battery 4. The emitter electrodes of the IGBTs 20b and 20f are respectively connected via resistors 7 and 8 to the negative terminal of the battery 4. The emitter electrodes of the IGBTs 20a, 20c and 20e are each connected to the control circuit 100. In addition, the junction between the IGBTs 20a and 20b, the junction between the IGBTs 20c and 20d, and the junction between the IGBTs 20e and 20f are each connected to the electric motor 3. The freewheeling diodes 21a, 21b, 21c, 21d, 21e and 21f are respectively connected between the emitter and collector electrodes of the IGBTs 20a, 20b, 20c, 20d, 20e and 20f.

Respective junctions between the IGBT 22b and the resistor 7, and between the IGBT 22f and the resistor 8, are connected to the control circuit 100. Voltages which are developed across the resistors 7 and 8, indicative of the level of current that is being supplied to the electric motor 3, are thereby inputted to the control circuit 100.

The capacitors 5 and 6 are connected in parallel across the battery 4. The capacitor 5 serves to smooth the output voltage of the battery 4, while the capacitor 6 serves to prevent electrical noise from entering the power module 2. In addition, both terminals of the battery 6 are connected to the control circuit 100, for enabling the control circuit 100 to detect the voltage applied by the battery 4 to the power module 2.

The control circuit 100 controls the power module 2 based upon the values of current supplied to the electric motor 3 from the power module 2 (as detected from the voltages developed across the resistors 7 and 8) and upon the voltage of the battery 4 as measured between the terminals of the capacitor 6.

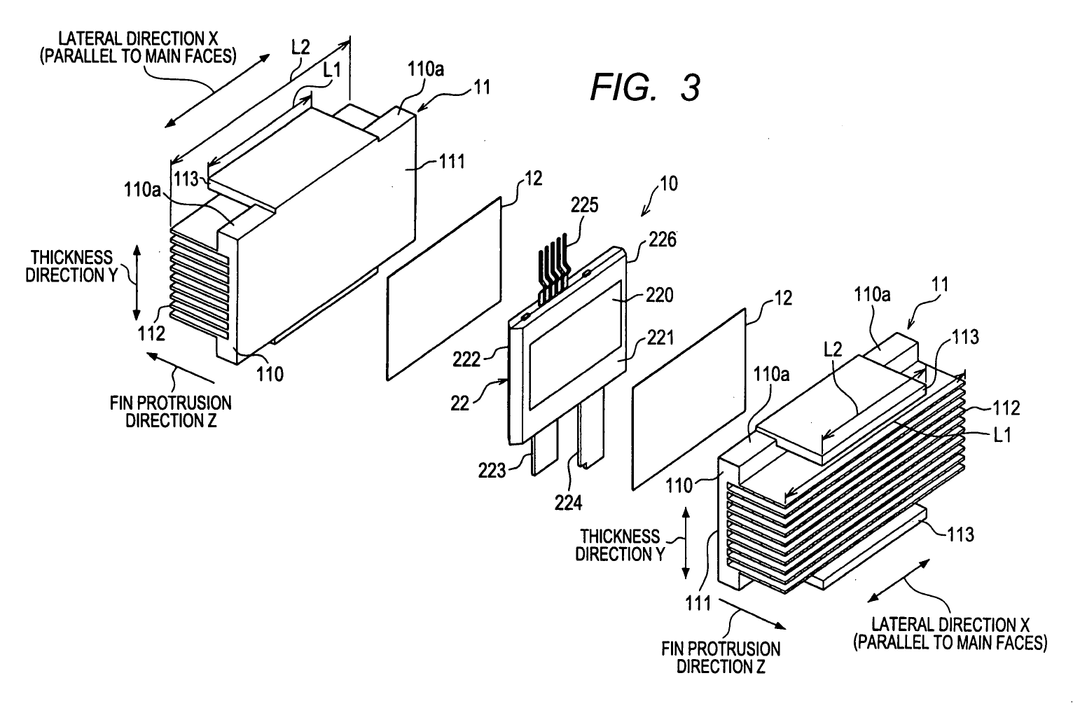

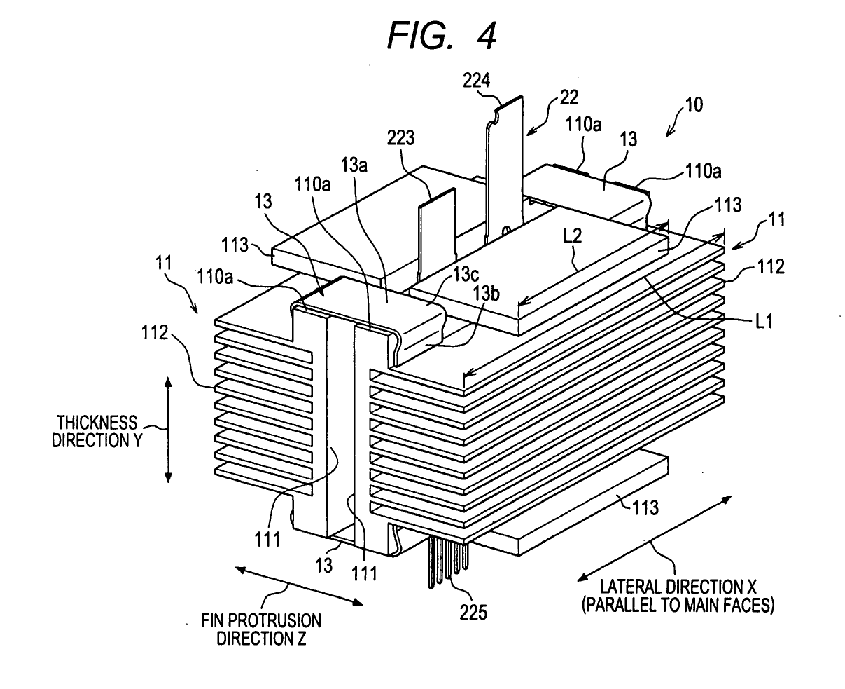

The configuration of a first embodiment of a semiconductor apparatus, designated by numeral 10, will be described referring to FIGS. 3 and 4 which respectively show an exploded view and an oblique external view of the apparatus. For ease of understanding, the view of FIG. 4 shows an inverted condition of the semiconductor apparatus 10, relative to that of FIG. 3. The semiconductor apparatus 10 has a semiconductor module 22, containing a pair of semiconductor elements as described above referring to FIG. 2, e.g., the IGBT 20a and freewheeling diode 21a. The semiconductor module 22 has the shape of a flat card, and basically consists of a module body 226 which internally contains the semiconductor elements and from which a collector-side terminal 223, an emitter-side terminal 224 and a set of control terminals 225 respectively protrude. A pair of heat sinks 11, of respectively identical configuration, are disposed on opposite sides of the module body 226. These opposite sides of the module body 226 are respectively formed with flat main faces 221 and 222. The opposing heat sinks 11 are disposed to be pressed against the main faces 221 and 222 of the module body 226 from opposite direction, to thereby retain the semiconductor module 22 while also effecting cooling of both sides of the semiconductor module 22.

On each side of the module body 226, an insulation plate 12 (providing electrical insulation) formed of ceramic is interposed between a main face 221, 222 of the module body 226 and the corresponding heat sink 11. A silicone type of thermally conductive grease is coated (before assembling the semiconductor apparatus 10) on surfaces of the main faces 221 and 222 of the module body 226, each insulation plate 12, and each heat sink 11, i.e., on those surfaces which come into mutual contact when the semiconductor apparatus 10 is assembled. The insulation plate 12 could alternatively be formed of aluminum nitrate film or silicon rubber sheet, or it might be possible to utilize only an electrically insulating type of thermally conductive film in place of the insulation plate 12, without applying thermally conductive grease.

One of the junctions between the semiconductor elements (IGBT and flywheel diode) of the semiconductor module 22 is joined by a solder layer to the inner side of a metallic thermal conduction plate 220, which is located in a rectangular region within the main face 221 of the module body 226 and which has an outer (flat) face which is substantially coplanar with the main face 221. The other junction between the IGBT and flywheel diode is joined by a solder layer to a second metallic thermal conduction plate 220 (not visible in the drawing) located on the opposite main face 222 of the module body 226. The IGBT and flywheel diode of the semiconductor module 22 are thereby electrically connected as shown in FIG. 2, i.e., with the emitter and collector of the IGBT and the anode and cathode of the flywheel diode connected in a reverse-parallel condition, while current flows to the collector-side terminal 223 and the emitter-side terminal 224 via respective ones of the two metallic thermal conduction plates 220. However, so long as the described electrical connections are established, it would be possible to use material other than solder as an attachment material.

As indicated in FIGS. 3 and 4, three mutually orthogonal X, Y and Z directions are referred to in the following as the lateral direction X (which is parallel to the main faces 221, 222), the thickness direction Y (also parallel to the main faces 221, 222) and the fin protrusion direction Z.

With this embodiment, the module body 226 has a rectangular shape and is formed of a synthetic resin material, which is molded to conform closely to the shapes of the semiconductor elements (IGBT and flywheel diode) of the semiconductor module 22. The molding is performed such that the outer faces of the metallic thermal conduction plates are exposed at respective ones of the main faces 221 and 222. The collector-side terminal 223 and the emitter-side terminal 224 respectively protrude from a face of the module body 226 that is parallel to the X-direction. The control terminals 225, which are connected to the gate electrode of the IGBT, etc, protrude from an opposite face of the module body 226 to that of the collector-side terminal 223 and emitter-side terminal 224, respectively extending in the opposite direction to the collector-side terminal 223 and emitter-side terminal 224.

Each heat sink 11 includes a base portion 110 having a main face 111 which becomes thermally coupled to a corresponding one of the main faces 221, 222 of the module body 226, and so becomes oriented parallel to the X-Y plane. The base portion 110 is integrally formed with a plurality of primary fins 112, each formed as a flat thin plate, which respectively protrude in the fin protrusion direction Z and are arrayed at equal spacings along the thickness direction Y. The heat sink 11 is preferably formed of aluminum or of copper.

The heat sink 11 also includes two secondary fins 113, integrally formed with the base portion 110 on the same side of the base portion 110 as the primary fins 112, with each of the secondary fins 113 extending in the fin protrusion direction Z. The secondary fins 113 are respectively positioned outside the outermost ones of the primary fins 112, as measured in the Y direction, and are oriented parallel to the primary fins 112.

With this embodiment, the thickness of each of the secondary fins 113 (i.e. as measured in the thickness direction Y) is uniform and is greater than the thickness of each of the primary fins 112, i.e., each secondary fin 113 is formed as a flat plate. However it should be noted that it would be equally possible to achieve the objectives of the present invention by making only a part of each of the secondary fins 113 of a heat sink 11 thicker than each of the primary fins 112. Alternatively, a configuration could be utilized whereby only a part of one of the secondary fins 113 of a heat sink 11 is made thicker than that of each of the primary fins 112 and the remaining one of these secondary fins 113 is formed as a flat plate having a uniform thickness which is greater than that of each of the primary fins 112.

In addition, each of the secondary fins 113 of a heat sink 11 is made shorter (as measured along the lateral direction X) than each of the primary fins 112, i.e., as illustrated in FIGS. 3 and 4, the dimension L2 is shorter than L1. In addition, each secondary fin 113 is located centrally on a base portion 110 (with respect to the lateral direction X). As a result two pairs of portions of the base portion 110 are formed, which do not have a part of a fin protruding therefrom, each pair located at opposite ends of a corresponding one of the secondary fins 113. These portions of a base portion 110, collectively designated as 110a in FIGS. 3 and 4, are referred to in the following as the fin-free portions, i.e., with each heat sink 11 having four fin-free portions 110a, and with each of the fin-free portions extending along the lateral direction X. The positions of the secondary fins 113 (with respect to the lateral direction X) correspond to that of the module body 226. The length L2 of each of the secondary fins 113 is made longer than the width L1 of the module body 226 as measured along the lateral direction X, so that the secondary fins 113 overlap the module body 226 with respect to the X direction.

As shown in FIG. 4, the semiconductor apparatus 10 includes four spring clips 13 which are each of approximately U-shaped cross-sectional shape, with each of the spring clips 13 engaging with the two heat sinks 11, such as to apply forces acting to clamp the module body 226 between the two opposing heat sinks 11. Each of the spring clips 13 is formed with a flat portion 13a, which is connected by curved portions 13c to opposing leg portions 13b. The leg portions 13b respectively contact a pair of opposing (with respect to the fin protrusion direction Z) fin-free portions 110a of respective heat sink 11, such that the leg portions 13b are forced outward, from positions which they attain when in an unattached condition.

With this embodiment, four spring clips 13 are utilized, disposed respectively outside the four corners of the module body 226, at identical spacings from these corners, so that forces are applied evenly to the module body 226 by the spring clips 13.

The forces thereby applied from the main faces 111 of the two heat sinks 11 securely clamp together the module body 226 of the semiconductor module 22, the two insulation plates 12 disposed on opposite sides of the module body 226, and the coatings of thermally conductive grease, between these main faces 111. The semiconductor apparatus 10 is thus maintained in the configuration shown in FIG. 4.

With this embodiment, the length of each of the spring clips 13 as measured in the lateral direction X is such that substantially the entirety of each of the corresponding fin-free portions 110a is occupied by the spring clip 13. Preferably, each of the spring clips 13 extends to a position which coincides with (or is closely adjacent to) the outer ends of the corresponding pair of fin-free portions 110a, as measured in the lateral direction X.

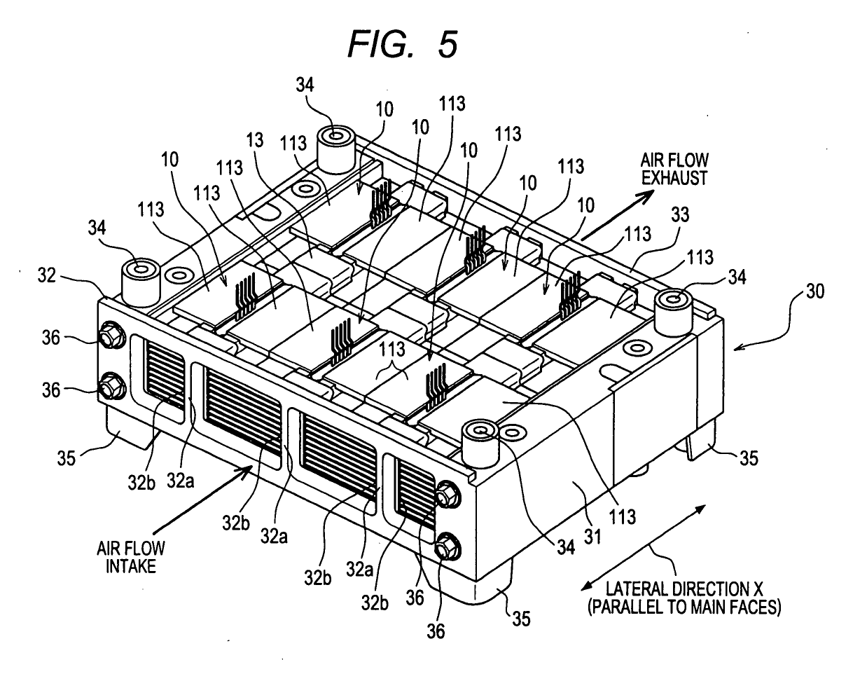

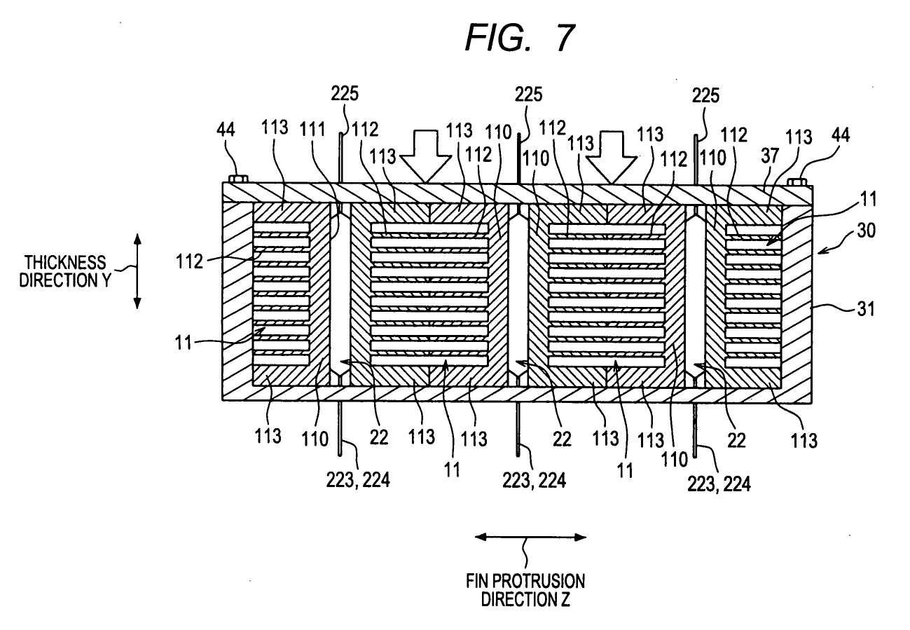

Since each semiconductor apparatus 10 implements a single semiconductor module 22, it is necessary to utilize a total of six semiconductor apparatuses 10 for implementing the power module 2 of FIG. 2 above. FIG. 5 shows an external oblique view of an inverter circuit unit 30 in which six semiconductor apparatuses 10 are installed, for this purpose, i.e., with the six semiconductor apparatuses 10 respectively containing the semiconductor modules 22a to 22f shown in FIG. 2. As shown in FIG. 5, the semiconductor apparatuses 10 are disposed immediately adjacent to one another, within a case 31. The case 31 has the general configuration of an open-top rectangular box, with openings formed in the lower side, through which the collector-side terminals 223 and emitter-side terminals 224 of the semiconductor apparatuses 10 protrude downward. In use, a lid 37 is installed on the case 31, for sealing the semiconductor apparatuses 10 within the interior of the case 31, as shown in the cross-sectional view of FIG. 7.

Two opposing sides of the case 31 are formed of respective ventilation passage-forming plates 32 and 33, each being of flat rectangular shape. A plurality of ventilation apertures collectively designated as 32b (with this embodiment, four ventilation apertures) are formed in the ventilation passage-forming plate 32, successively arrayed in parallel with one another along the fin protrusion direction Z of the semiconductor apparatuses 10. A correspondingly positioned set of four ventilation apertures 32b are similarly formed in the ventilation passage-forming plate 33, i.e., with each ventilation aperture 32b of the ventilation passage-forming plate 33 having the same Z-direction position and dimensions as a corresponding ventilation aperture 32b of the ventilation passage-forming plate 32. During actual operation, the ventilation apertures 32b of the ventilation passage-forming plate 32 function as upstream ventilation apertures, through which a cooling air flow passes into the inverter circuit unit 30, impelled by the fan 9 shown in FIG. 1 above. The ventilation apertures 32b of the ventilation passage-forming plate 33 function as downstream ventilation apertures, from which the cooling air passes out of the case 31 and is thereafter exhausted to the exterior of the vehicle.

The ventilation passage-forming plates 32 and 36 are attached to the other opposing side faces of the case 31 by screws 36, positioned at the four corners of each of the ventilation passage-forming plates 32 and 36. The lid 37 and the ventilation passage-forming plates 32 and 33 are each formed of a synthetic resin material.

During manufacture, the six semiconductor apparatuses 10 are set into respective predetermined positions by downward insertion into the case 31. As shown, the semiconductor apparatuses 10 are arranged as a rectangular array of three pairs of units, each pair being oriented along the X-direction, and the three pairs successively disposed along the Z-direction.

Of the three pairs of semiconductor apparatuses 10, one pair contain the semiconductor modules 22a, 22b, which respectively constitute the upper arm and lower arm of one of the three (U, V, W) phases, the second pair contain the semiconductor modules 22c, 22d, which respectively constitute the upper arm and lower arm of a second one of the phases, and the third pair contains the semiconductor modules 22c, 22d, which respectively constitute the upper arm and lower arm of the remaining phase.

The dimensions of the case 31 are determined such that the semiconductor apparatuses 10 are packed closely together against one another and against the inner faces of the case 31. Furthermore as can be understood from FIG. 7, the dimensions of the case 31 are determined such that when the lid 37 is installed, upper and lower faces of the semiconductor apparatuses 10 pressed against the inner face of the lid 37. Motion of the semiconductor apparatuses 10 relative to one another, or relative to the case 31 or lid 37, is thereby suppressed. Damage to the semiconductor apparatuses 10 resulting from shocks or vibration of the vehicle can thus be effectively prevented, without requiring additional components for fixedly securing the semiconductor apparatuses 10.

In that condition, the connection terminals 225 of the semiconductor apparatuses 10 protrude upward, through corresponding apertures (not shown in the drawings) formed in the lid 37, while the collector-side terminals 223 and emitter-side terminals 223 protrude downward, through corresponding apertures (not shown in the drawings) formed in the lower side of the case 31.

As illustrated in FIG. 5, each pair of adjacent ventilation apertures 32b are separated by a partition section 32a. The partition sections 32a (provided on the ventilation passage-forming plate 32, and also at identical locations on the ventilation passage-forming plate 33) are respectively disposed at positions along the Z-direction which do not correspond to positions of the primary fins 112 of the semiconductor apparatuses 10, i.e., at Z-direction positions corresponding to those of the respective module bodies 226 of the semiconductor apparatuses 10. Thus, each of the sets of primary fins 112 of the semiconductor apparatuses 10 is located at a Z-direction position corresponding to a pair of ventilation apertures 32b located respectively in the ventilation passage-forming plates 32 and 33.

A flow of cooling air (impelled from the fan 9) is branched into the respective ventilation apertures 32b of the ventilation passage-forming plate 32, passes in the X-direction between the primary fins 112 of the semiconductor apparatuses 10, and exits through the corresponding ventilation apertures 32b of the ventilation passage-forming plate 33. It can be understood that such a configuration ensures efficient cooling of the semiconductor apparatuses 10, since the locations of the partition sections 32a ensure that there is a minimum of obstruction to the flow of air through the arrays of primary fins 112, and since the direction of air flow through the interior of the inverter circuit unit 30 is parallel to the main faces of the primary fins 112 and secondary fins 113 of the heat sinks 11.

Hence, during operation of the inverter circuit unit 30, heat which is generated by each semiconductor module 22 is transferred through the insulation plates 12 on either side (passing through the coatings of thermally conductive grease formed on both sides of each insulation plate 12), to the base portions 110 of the heat sinks 11 located on opposing sides of the semiconductor module 22, and hence to the primary fins 112 of these heat sinks 11. The heat is then dissipated by the cooling air flow which passes through the spaces between adjacent primary fins 112. Effective cooling of each of the semiconductor modules 22 is thereby achieved.

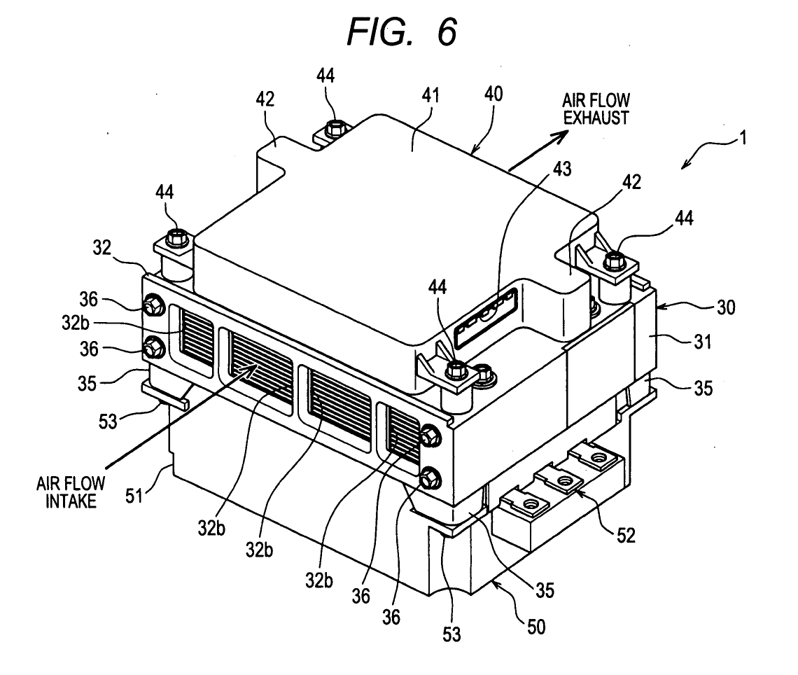

FIG. 6 is an oblique external view of the inverter apparatus 1, which controls the electric motor 3. As shown, the inverter circuit unit 30 is made up of a capacitor unit 50, the inverter circuit unit 30, and a control circuit unit 40, which are stacked successively and attached together to constitute a single unit. The capacitor unit 50 contains the capacitors 5 and 6 shown in FIG. 2, installed within a case 51. The control circuit unit 40 contains a control circuit board on which is formed the control circuit 100, enclosed in a case 41.

Four attachment legs 35 are formed at corner positions on the lower side of the case 31, each having a threaded hole therein, for use in attaching the case 51 of the capacitor unit 50 to the underside of the inverter circuit unit 30 by means of screws.

Similarly, as shown in FIG. 5, four attachment legs 34 are formed at corner positions on the upper side of the case 31, each having a threaded hole therein, for use in attaching the case 41 of the control circuit unit 40 to the upper side of the inverter circuit unit 30 by screws 44. When assembling the inverter circuit unit 30, the control circuit board constituting the control circuit 100 is first attached to the case 31 of the inverter circuit unit 30, e.g., by means of screw attachment (not shown in the drawings). The case 41 is then lowered onto the case 31 of the inverter circuit unit 30, thereby enclosing the control circuit board of the control circuit 100, and the case 41 is then fixedly secured to the case 31 by engaging the screws 44 in the threaded holes of the attachment legs 34.

As shown in FIG. 6, when the inverter circuit unit 30 has been assembled, respective output terminals 52 of the three (U, V, W) phases are exposed to the exterior of the case 31 of the inverter circuit unit 30, for enabling connection to corresponding supply leads of the electric motor 3. Another externally exposed terminal (not shown in the drawings) is also provided, for connecting a power supply input lead from the battery 4. In addition, a set of connection terminals 43 are exposed to the exterior of the case 41 of the control circuit unit 40, for connection of a power supply lead (for the control circuit 100) and of signal leads (transferring signals between the vehicle ECU and the control circuit 100). The case 41 is also formed with a connecting lead conduit portion 42, which internally accommodates wiring that is connected between the control circuit unit 40 and the inverter circuit unit 30 and capacitor unit 50. Each of the cases 41 and 51 is formed of a synthetic resin material.

The function of the secondary fins 113 will be described more specifically in the following referring to the cross-sectional view of FIG. 7, showing the heat sinks 11 contained within the case 31 of the inverter circuit unit 30, with the lid 37 attached to the case 31 by the screws 44. The dimensions of the case 31 are predetermined such that in the condition shown in FIG. 7, the underside of each heat sink 11 is held pressed against the upper internal main face of the case 31, while the uppermost side of each heat sink 11 is held pressed against the lower internal main face of the lid 37, i.e., opposing (upward and downward) forces acting along the thickness direction Y are applied to each of the heat sinks 11, by the case 31 and the lid 37.

If the secondary fins 113 were to be omitted, then since it is necessary for each of the primary fins 112 to be substantially thin (to achieve a sufficient efficiency of heat transfer, with a compact apparatus configuration, as described hereinabove), these forces acting on the upper and lower sides of each heat sink 11 could result in deformation of the primary fins 112. However with this embodiment, by incorporating the secondary fins 113 above and below each set of primary fins 112, with each secondary fin 113 being substantially thicker than each primary fin 112 and hence having greater strength than the primary fins 112, fin deformation can be prevented. The total number of primary fins can thereby be increased, enabling a semiconductor apparatus 10 to be of compact size while maintaining a sufficient level of thermal transfer efficiency for the heat sinks 11.

Incorporation of the secondary fins 113 in each heat sink 11 also provides the following advantage. When heat is generated by the semiconductor elements and is transferred via a insulation plate 12 etc., as described above, to the base portion 110 of a heat sink 11, the heat then flows to the primary fins 112 and also to the secondary fins 113, which are formed integrally with the base portion 110. Since each secondary fin 113 is made thicker than each primary fin 112, and so has a greater volume per unit of length (as measured along the lateral direction X) than each primary fin 112, each secondary fin 113 has greater thermal capacity than a primary fin 112, i.e., has a greater capability for temporarily storing heat than does a primary fin 112. The thermal mass of each heat sink 11 is thereby increased (by comparison with the case in which the space occupied by each secondary fin would be occupied by a plurality of primary fins).

When there is a change in the amount of heat generated by the semiconductor elements of a semiconductor apparatus 10, the temperature of the semiconductor elements thereafter gradually varies, until a steady-state temperature is attained. With this embodiment, due to the increased thermal mass which is provided by the secondary fins 113 of each heat sink 11, the rate of temperature variation of the semiconductor elements becomes more gradual than for the case in which the secondary fins 113 are not incorporated. This serves to reduce the thermal stress applied to the semiconductor elements, which can ensure a longer operating life for these.

Furthermore this embodiment of a semiconductor apparatus 10 provides the following advantage when incorporated in the inverter circuit unit 30. When heat passes from the semiconductor elements of a semiconductor apparatus 10 via each base portion 110 to the secondary fins 113 of each heat sink 11, the heat is rapidly transferred to each secondary fin 113 due to the increased thermal transfer capability of these fins, resulting from the increased thickness. The heat is thereafter dissipated to the exterior of the heat sink 11. Sudden increases in the temperature of the semiconductor modules 22 of the semiconductor apparatuses 10, due to sudden increases in amounts of power dissipated by the semiconductor elements, can thereby be prevented. That is, considering the heat sinks 11 as a thermal transfer system, the system has a rapid response to sudden increases in power that is generated as heat by the semiconductor elements.

In addition, concerning the inverter circuit unit 30, heat is efficiently transferred from each of the semiconductor apparatuses 10 from the sets of primary fins 112 disposed on opposite sides of the module body 226 of each semiconductor apparatus 10, as the cooling air flow impelled by the fan 9 passes through the spaces between the primary fins 112.

Furthermore with regard to the inverter circuit unit 30, if the secondary fins 113 were not provided, the primary fins 112 of the heat sinks 11 could become deformed when the semiconductor apparatuses have become installed within the case 31, in contact with (or closely adjacent to) other semiconductor apparatuses or internal surfaces of the case 31 and lid 37. Such distortion of the primary fins 112 could reduce the spaces between adjacent fins, and so obstruct the flow of cooling air through these spaces. However by providing the secondary fins 113, it is ensured that such deformation of the primary fins 112 is avoided, thereby ensuring efficient cooling of the semiconductor modules 22 by the heat sinks 11.

In addition to the above advantages, the semiconductor apparatus 10 of this embodiment provides ease of manufacture, since the number of components required to assemble each semiconductor apparatus 10 is small, and the assembly operation can simple. Specifically, by making each secondary fin 113 shorter than each primary fin 112 (as measured along the lateral direction X), two pairs of fin-free portions 110a are formed on each heat sink 11, each pair respectively located at the outer ends of a secondary fin 113 (with respect to the lateral direction X). Spring clips 13 can thereby be mounted on respective fin-free portions of the opposed heat sinks 11 of a semiconductor apparatus 10, at each of the corners of the heat sinks, for applying spring forces acting to clamp the semiconductor module 20 between these heat sinks 11, in the condition illustrated in FIG. 4. A semiconductor apparatus 10 can thereby be assembled as an integral unit without requiring screws or other attachment elements for that purpose. In that condition, the main faces 111 of the respective base portions 110 of opposing heat sinks 11 are securely held against the main faces 221 of a semiconductor module 22, so that efficient transfer of heat from each semiconductor module 22 to the heat sinks 11 is achieved. Furthermore since heat is transferred from both sides of each semiconductor module 22 to the corresponding pair of heat sinks 11, effective cooling is ensured, further enabling each semiconductor apparatus 10 to be of compact size.

Furthermore with an inverter circuit unit 30 which incorporates a set of six semiconductor apparatuses 10 each configured in accordance with the above embodiment, the upper arm and lower arm of each phase can be respectively implemented by a pair of semiconductor apparatuses 10 in accordance with the first embodiment, which are located immediately adjacent to one another (along the lateral direction X, as illustrated in FIG. 5), with the primary fins 112 of each of these pairs of semiconductor apparatuses 10 being mutually parallel and at respectively identical positions along the thickness direction Y (as illustrated in FIG. 7). In that condition, by passing a flow of cooling air along the lateral direction X successively through the respective sets of primary fins 112 of such an adjacent pair of semiconductor apparatuses 10, efficient transfer of heat from the heat sinks to the atmosphere can be achieved.

In addition to the above advantages, due to the increased strength of each semiconductor apparatus 10 which results from incorporation of the secondary fins 113, it becomes possible to pack a plurality of semiconductor apparatuses 10 closely together within a case, i.e., with the semiconductor apparatuses 10 being held in contact with one another and with interior surfaces of the case. The overall size of the inverter circuit unit 30 can thereby be made compact. Furthermore, with the semiconductor apparatuses 10 packed closely together within a case in such a condition, there is a reduced danger of damage to the semiconductor apparatuses 10 as a result of vibration. In particular when an apparatus such as the inverter circuit unit 30 is installed in an electric vehicle, high levels of vibration must be sustained. Use of semiconductor apparatuses 10 in accordance with the above embodiment can ensure increased reliability for such an apparatus.

Furthermore in the case of an apparatus such as the inverter circuit unit 30, since the apparatus may be configured using six semiconductor device units (i.e., six semiconductor apparatuses 10) which are identical to one another, the number of parts required in manufacturing such an apparatus can be reduced, and manufacturing costs reduced.

### Second Embodiment

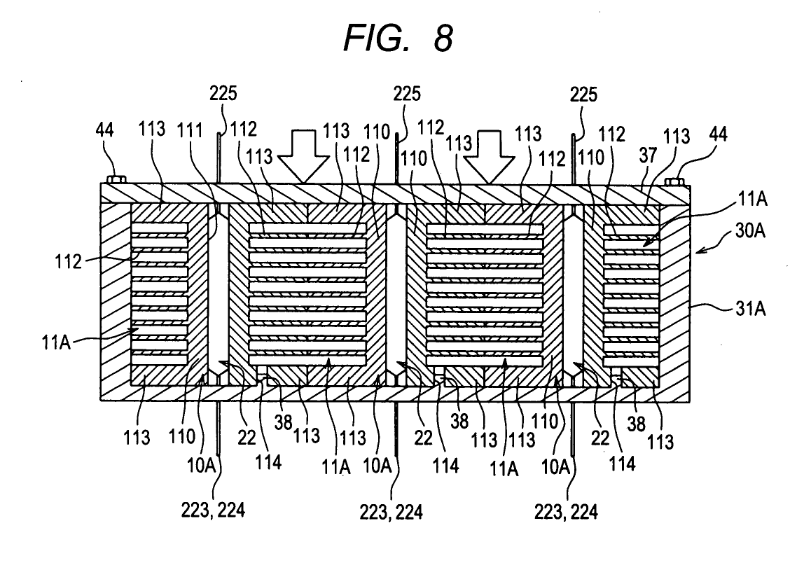

A second embodiment of a semiconductor apparatus will be described referring to FIG. 8, which shows an inverter circuit unit 30A having identical functions and operation to those of the inverter circuit unit 30 described above. In FIG. 8, each of respective semiconductor apparatuses 10A differs from the semiconductor apparatus 10 of the first embodiment only in that an aperture (with this embodiment, a through-hole 114) extending in the thickness direction Y is formed in one of the secondary fins 113 of one of the heat sinks 11 of the semiconductor apparatus 10A. Specifically, for each semiconductor apparatus 10A, the through-hole 114 is formed in one of the secondary fins 113 (i.e., in one of the pair of fins which contact the lower inner face of the case 31A). The lower inner face case 31A of the case 31 of the 30ax is formed with an array of protrusions 38 (each extending in the thickness direction Y). The respective positions of the protrusions 38, and the dimensions of each of the protrusions 38, are determined such that when six semiconductor apparatuses 10A are installed within the case 31A (by downward insertion) at appropriate predetermined positions, each of the protrusions 38 engages within a corresponding one of the through-hole 114. The respective positions of the six semiconductor apparatuses 10A within the case 31A can thereby be definitively established, while making effective use of the thickness of each secondary fin 113, which enables apertures of sufficient length to be formed for securely engaging with the protrusions of the case 31A.

Positioning of the semiconductor apparatuses 10A of the inverter circuit unit 30A can thereby be effected very simply, without requiring the use of additional components for that purpose.

### Third Embodiment

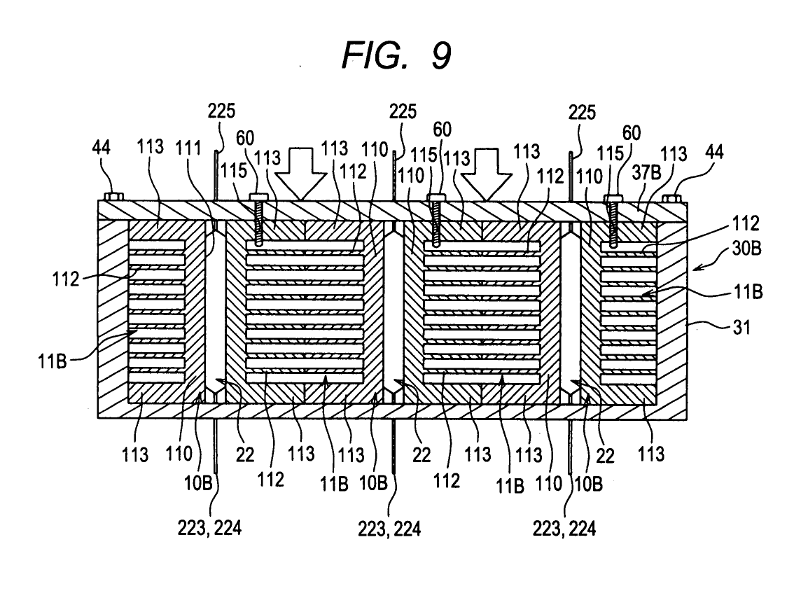

A third embodiment of a semiconductor apparatus will be described referring to FIG. 9, which shows an inverter circuit unit 30B having identical functions and operation to those of the inverter circuit unit 30 described above. In FIG. 9, each of respective semiconductor apparatuses 10B differs from the semiconductor apparatus 10 of the first embodiment only in that a threaded hole 115 (extending in the thickness direction Y) is formed in one of the secondary fins 113 of one of the heat sinks 11 of the semiconductor apparatus 10B, with the holes being threaded in correspondence with a set of screws 60. Specifically, for each semiconductor apparatus 10B, the threaded hole 115 is formed in one of the pair of secondary fins 113 of that semiconductor apparatus 10B which each become placed in contact with the lid 37B when the inverter circuit unit 30A is assembled. Six through-holes (each extending in the thickness direction Y) are provided in the lid 37B. The respective positions of these through-holes are determined such when six semiconductor apparatuses 10B have been installed within the case 31 at respective predetermined provisional positions and the lid 37B is then mounted on the case 31, the locations of the through-holes in the lid 37B respectively correspond to the locations of the threaded holes 115. In that condition, the screws 60 are then passed through respective ones of the through-holes, engaged in the threaded holes 115 and tightened.

The semiconductor apparatuses 10A can thereby be securely fixed at respective appropriate positions within the inverter circuit unit 30B. This embodiment makes effective use of the thickness of each secondary fin 113, since the thickness can enable each of the threaded holes 115 to be sufficiently long to accommodate a sufficient number of threads for securely retaining each screw 60. It thereby becomes unnecessary to provide additional components such as nuts, for attaching the semiconductor apparatuses 10B by the screws 60.

### Fourth Embodiment

FIG. 4 is an oblique external view of a fourth embodiment of a semiconductor apparatus, designated as 10C. In FIG. 4, components having corresponding functions to those of the first embodiment are designated by identical reference numerals to those of the first embodiment. This embodiment essentially differs from the first embodiment only by incorporating two semiconductor modules 22 instead of a single module, and having a different number and dispositions of the spring clips 13.

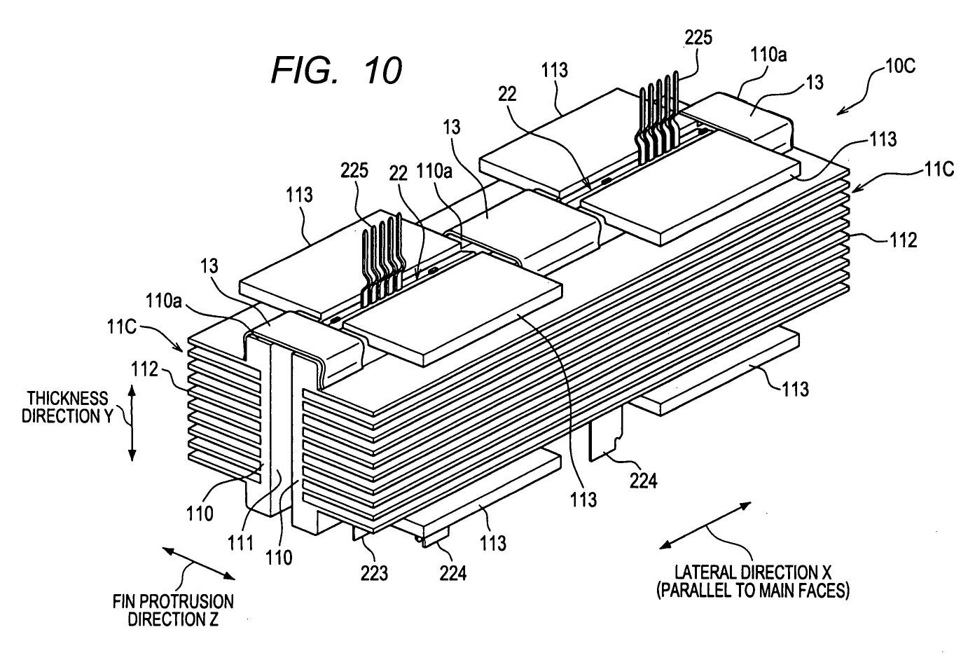

In the semiconductor apparatus 10C, two semiconductor modules 22 are disposed in parallel along the lateral direction X, at identical positions with respect to the thickness direction Z. The two semiconductor modules 22 are enclosed between two opposing heat sinks 11C. Respective base portions 110 of the two heat sinks 11C are thermally coupled to the main faces 221, 222 of the two semiconductor modules 22. Each of the heat sinks 11C has a plurality of primary fins 112 and two pairs of secondary fins 113, respectively protruding in the thickness direction Z from the base portion 110. Each pair of secondary fins 113 consists of an upper fin and a lower fin, which are respectively located outside (with respect to the thickness direction Y) the outermost ones of the primary fins 112 of the heat sink 11C. The secondary fins 113 are of identical length (as measured along the lateral direction X), with each secondary fin 113 being shorter than each primary fin 112, and with the secondary fins being respectively located such as to provide six fin-free portions 110a on the base portion 110 of the heat sink 11C. As can be understood from FIG. 10, these consist of three pairs of fin-free portions 110a, with the fin-free portions 110a of each pair being located respectively at the upper side and the lower side of the heat sink 11C, with four of the fin-free portions 110a being located at respective corners of the base portion 110 of the heat sink 11C, and with one pair of fin-free portions 110a being located centrally on the base portion 110. Three pairs of spring clips 13 are mounted on respective fin-free portions 110a of the opposing pair of heat sinks 11C, disposed to clamp together the respective base portions 110 of these heat sinks 11C, and thereby fixedly retain the pair of semiconductor modules 22 between the two heat sinks 11C. It will be understood that an inverter circuit unit having essentially similar functions and configuration to the above-described inverter circuit unit 30 can be configured by disposing three semiconductor apparatuses 10C within a case at appropriate positions, i.e., respectively corresponding to the three pairs of adjacent semiconductor apparatuses 10 shown in FIG. 5 above. That is to say, the three semiconductor apparatuses 10C would be disposed successively adjacent along the fin protrusion direction Z, with the functions of the three semiconductor apparatuses 10C respectively corresponding to those of the three pairs of adjacent semiconductor apparatuses 10 shown in FIG. 5, i.e., respectively implementing the U, V and W phases of the inverter circuit unit 30. It will thus be understood that similar effects can be achieved with this embodiment of a semiconductor apparatus to those described for the first embodiment.

### Alternative Embodiments

The present invention as claimed in the appended claims is not limited in scope to the above embodiments, and various alternative embodiments or modified forms of the above embodiments may be envisaged, as exemplified by the following.

With the above embodiments the secondary fins are each formed with uniform thickness. However it would be equally possible to make only one part (or a plurality of parts) of each secondary fin substantially thicker than each of the primary fins.

Moreover although each of the above embodiments utilizes IGBTs as semiconductor elements (functioning as switching elements) formed on respective semiconductor chips, it would be equally possible to utilize other types of device, such as MOSFETs (Metal Oxide Semiconductor Field Effect Transistors), JFETs (Junction Gate Field Effect Transistors), etc.

Furthermore, motors which are driven by the above examples of inverter apparatus are not limited to being drive motors (motive power motors) of vehicles, but could be applied to various other applications, such as for driving electrical generators, or as engine starter motors, compressor drive motors, etc.

What is claimed is:

1. A semiconductor apparatus comprising a semiconductor module containing semiconductor elements, said semiconductor module formed with opposing sides thereof having respective external main faces, a pair of heat sinks disposed to enclose said opposing sides of said semiconductor module, each of said heat sinks formed with a base portion having a first side that is thermally coupled to a corresponding one of said main faces, and each of said heat sinks formed with a plurality of primary fins respectively protruding from a second side of said base portion, opposite to said first side, said primary fins being arrayed along a thickness direction at regular spacings,
wherein each of said heat sinks comprises at least one pair of secondary fins, each of said secondary fins having at least a part thereof formed with a thickness, as measured along said thickness direction, which is greater than a thickness of each of said primary fins, and with secondary fins of said pair being located respectively outward from an outermost pair of said primary fins, as measured along said thickness direction.

2. A semiconductor apparatus as claimed in claim 1, wherein each of said secondary fins is shorter than each of said primary fins, as measured along a lateral direction that is perpendicular to said thickness direction and parallel to said main faces, thereby forming a plurality of fin-free portions of said second side of said base portion, each of said fin-free portions containing no part of a secondary fin or primary fin;
and comprising a plurality of spring clips each disposed to engage with corresponding fin-free portions formed on respective ones of said pair of heat sinks, for applying spring force to clamp said pair of heat sinks together and thereby fixedly retain said semiconductor module between said pair of heat sinks.

3. A semiconductor apparatus as claimed in claim 2, wherein said fin-free portions comprise two pairs of fin-free portions, each of said pairs being located at respectively opposing ends of a corresponding one of said secondary fins, with respect to said lateral direction.

4. A semiconductor apparatus as claimed in claim 1, wherein said semiconductor apparatus is configured to be contained within a case, mounted upon an interior face of said case, wherein said thickness portion of one of said secondary fins of at least one of said pair of heat sinks is formed with an aperture and said interior face of said case is formed with a protrusion, said protrusion being formed and located such as to engage within said aperture when said semiconductor apparatus is installed at a predetermined position within said case.

5. A semiconductor apparatus as claimed in claim 1, wherein
said semiconductor apparatus is configured to be contained within a case, and said thick portion of one of said secondary fins of said pair of heat sinks is formed with a threaded hole configured in accordance with a screw, and
said case is formed with a through-hole having a location which corresponds to a location of said threaded hole when said semiconductor apparatus is installed at a predetermined position within said case;
said semiconductor apparatus being thereby enabled to be fixedly retained within said case by engaging said screw within said threaded hole, with said screw passed through said through-hole.

6. A three-phase rectifier apparatus comprising a three-phase rectifier circuit having three circuit sections corresponding to respective ones of three phases, each of said circuit sections formed of interconnected circuit elements constituting an upper arm of a phase and interconnected circuit elements constituting a lower arm of a phase;
wherein said upper arm and said lower arm of each of said phases are implemented by respective semiconductor modules of a pair of semiconductor apparatuses, each of said semiconductor apparatuses being as claimed in claim 1.

7. A three-phase rectifier apparatus as claimed in claim 6, wherein said semiconductor apparatuses are contained in common within a case, and comprising ventilation means configured to transfer heat dissipated by said primary fins and secondary fins of said heat sinks of said semiconductor apparatuses to the atmosphere.

8. A three-phase rectifier apparatus as claimed in claim 7, wherein said ventilation means comprises
a fan which is driven for impelling a cooling air flow, and
at least one opposed pair of ventilation apertures formed in said case, located for passing said cooling air flow through spaces between said primary fins and between said secondary fins and said primary fins of said heat sinks, along a direction parallel to main faces of said primary fins, said opposed pair of ventilation apertures comprising an intake ventilation aperture disposed to receive said cooling air flow from said fan and an exhaust ventilation aperture disposed for exit of said cooling air from said case.

9. A three-phase rectifier apparatus as claimed in claim 8 wherein said case is formed with a plurality of said opposed pairs of ventilation apertures, respectively located in accordance with positions of said semiconductor apparatuses within said case,
each of said opposed pairs of ventilation apertures being configured for passing a part of said cooling air flow, in succession, through spaces between respective primary fins of a plurality of said heat sinks of said semiconductor apparatuses.
